(19) United States
(12) Patent Application Publication
(10) Pub. No.: US 2026/0356080 A1
(43) Pub. Date: Nov. 12, 2026

(54) GRAPHITE COMPOSITE AND METHOD FOR PRODUCING GRAPHITE COMPOSITE

(71) Applicant: KANEKA CORPORATION, Osaka (JP)

(72) Inventors: Takeshi NAKAGAKI, Tokyo (JP); Motoaki KOBAYASHI, Osaka (JP)

(73) Assignee: KANEKA CORPORATION, Osaka (JP)

(21) Appl. No.: 19/717,879

(22) Filed: Jun. 24, 2026

Related U.S. Application Data
(63) Continuation of application No. PCT/JP2024/039240, filed on Nov. 5, 2024.

(30) Foreign Application Priority Data
Dec. 26, 2023 (JP) 2023-219656

(51) Int. Cl. B32B 9/00; B32B 7/12; B32B 9/04

(52) U.S. Cl. CPC B32B 9/007; B32B 7/12; B32B 9/041; B32B 2250/05; B32B 2305/08; B32B 2307/704; B32B 2307/7376; B32B 2311/04; B32B 2311/12; B32B 2311/22

(57) ABSTRACT

A graphite composite having excellent thermal diffusion ability, reduced susceptibility of anisotropic graphite to cracking, excellent heat resistance, and a reduced degree of warpage includes anisotropic graphite in which, in XYZ space, crystal orientation planes of graphite layers are disposed in parallel to the X-Z plane. The anisotropic graphite has a first principal face and a second principal face, each parallel to the X-Y plane; a first metal layer on the first principal face and a second metal layer on the second principal face, each having a specific thickness; and an adhesive layer and a reinforcing layer, each parallel to the Y-Z plane.

### CROSS-REFERENCE TO RELATED APPLICATIONS

This application claims benefit of priority to International Patent Application No. PCT/JP2024/039240, filed Nov. 5, 2024, and to Japanese Patent Application No. 2023-219656, filed Dec. 26, 2023, the entire contents of each are incorporated herein by reference.

### BACKGROUND

### Technical Field

The present disclosure relates to a graphite composite and a method for producing a graphite composite.

### Background Art

Graphite is widely used as an element for transferring and dissipating heat generated from electronic equipment and devices.

In particular, anisotropic graphite, which has a structure in which six-membered rings of carbon atoms are linked together by covalent bonds and layers of the graphite structures are joined by Van der Waals forces, has high thermal conductivity. Accordingly, anisotropic graphite has been attracting attention as an element for effectively transferring and dissipating heat generated from electronic equipment and devices.

For example, WO 2019/188915 A1 discloses anisotropic graphite and an anisotropic graphite composite, each having excellent heat transmission performance and long-term reliability as a heat-transmitting element, and a method for producing the same. In the technique described in WO 2019/188915 A1, a titanium-containing metal layer and an inorganic material layer, etc., are formed above a principal face of anisotropic graphite.

### SUMMARY

### Technical Problem

Conventional techniques as described above are sophisticated. However, in such conventional techniques, there has been room for improvement in terms of thermal diffusion ability, reduction in susceptibility of anisotropic graphite to cracking, better heat resistance, and reduction in degree of warpage.

An object of the present disclosure is to achieve a graphite composite having excellent thermal diffusion ability, reduced susceptibility of anisotropic graphite to cracking, excellent heat resistance, and a reduced degree of warpage.

A graphite composite according to an embodiment of the present disclosure is a graphite composite including anisotropic graphite in which, given an X axis, a Y axis orthogonal to the X axis, and a Z axis perpendicular to the X-Y plane, crystal orientation planes of graphite layers are disposed in parallel to the X-Z plane, the anisotropic graphite having a first principal face parallel to the X-Y plane and a second principal face opposing the first principal face; a first metal layer provided on the first principal face of the anisotropic graphite; a second metal layer provided on the second principal face of the anisotropic graphite; and an adhesive layer and a reinforcing layer provided on at least one face of the two faces in the anisotropic graphite that are parallel to the Y-Z plane. The first metal layer and the second metal layer each have a thickness of 2 μm to 50 μm, and the adhesive layer contains resin.

A method for producing a graphite composite according to an embodiment of the present disclosure is a method for producing a graphite composite including anisotropic graphite in which, given an X axis, a Y axis orthogonal to the X axis, and a Z axis perpendicular to the X-Y plane, crystal orientation planes of graphite layers are disposed in parallel to the X-Z plane, the anisotropic graphite having a first principal face parallel to the X-Y plane and a second principal face opposing the first principal face. The method includes a reinforcing step of forming a reinforcing layer on at least one face of the two faces of the anisotropic graphite that are parallel to the Y-Z plane, in which the anisotropic graphite and the reinforcing layer are adhered together via an adhesive layer; and a metal layer formation step of forming a first metal layer and a second metal layer respectively on the first principal face and second principal face of the anisotropic graphite with the reinforcing layer formed thereon. The first metal layer and the second metal layer each have a thickness of 2 μm to 50 μm, and the adhesive layer contains resin.

An aspect of the present disclosure can provide a graphite composite having excellent thermal diffusion ability, reduced susceptibility of anisotropic graphite to cracking, excellent heat resistance, and a reduced degree of warpage.

### BRIEF DESCRIPTION OF THE DRAWINGS

FIG. 1 is a diagram illustrating the configuration of a graphite composite according to an embodiment of the present disclosure.

FIG. 2 is a diagram illustrating steps of a method for producing a graphite composite according to an embodiment of the present disclosure.

FIG. 3 is a diagram illustrating the configurations of a test sample and testing apparatus used for evaluation test on heat transmission performance in Examples of the present disclosure.

### DETAILED DESCRIPTION

An embodiment of the present disclosure is described below, but the present disclosure is not limited thereby. The present disclosure is not limited to configurations described below, and various modifications within the scope shown in the claims are permitted. Embodiments or examples given by combining technical means disclosed for different embodiments or examples are also included in the technical scope of the present disclosure. Furthermore, a new technical feature can be formed by combining technical means disclosed for different embodiments. All of the academic documents and patent literatures cited herein are incorporated herein as references. Unless otherwise specified, “A to B” showing a numerical range herein means “A or more (including A and being more than A) and B or less (including B and being less than B)”.

### [1. Basic Principle of Present Disclosure]

As described above, in the technique described in WO 2019/188915 A1, a titanium-containing metal layer and an inorganic material layer, etc., are formed above a principal face of anisotropic graphite. The inorganic material layer formed above a principal face of anisotropic graphite exhibits a tendency to inhibit the excellent thermal diffusion ability of anisotropic graphite. In addition, anisotropic graphite has a character of susceptibility to cracking along crystal orientation planes of graphite layers.

The present inventors have discovered the features and characteristics shown in the following (i) to (iv) to arrive at the present disclosure.
(i) Anisotropic graphite can be made less susceptible to cracking by a reinforcing layer having a unique disposition.
(ii) Since the reinforcing layer is provided, a layer surrounding the anisotropic graphite can be made thin, and the configuration of the layer surrounding the anisotropic graphite can be simplified, whereby the thermal diffusion ability of the graphite composite can be improved.
(iii) The anisotropic graphite can be made further less susceptible to cracking by the thin layer surrounding the anisotropic graphite.
(iv) The degree of warpage of the anisotropic graphite can be reduced by an adhesive layer having a unique disposition and composition.

Here, the layer surrounding the anisotropic graphite is, for example, a metal layer such as a first metal layer and a second metal layer. Also, simplifying the configuration of the layer surrounding the anisotropic graphite is, for example, making the configuration provided on the principal faces of the anisotropic graphite consist only of the first metal layer and the second metal layer.

An aspect of the present disclosure can provide a graphite composite having excellent thermal diffusion ability, reduced susceptibility of anisotropic graphite to cracking, excellent heat resistance, and a reduced degree of warpage. The effects according to an aspect of the present disclosure may contribute, for example, even to the achievement of Goal 12 “Ensure sustainable consumption and production patterns” of Sustainable Development Goals (SDGs) proposed by the United Nations.

### [2. Graphite Composite]

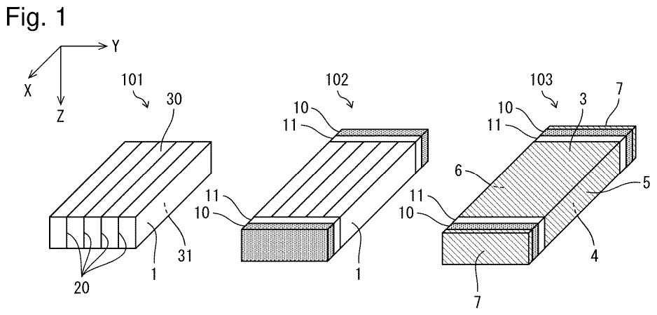

A graphite composite according to an embodiment of the present disclosure will be described with reference to FIG. 1. FIG. 1 is a diagram illustrating the configuration of a graphite composite according to an embodiment of the present disclosure.

A graphite composite 103 according to an embodiment of the present disclosure is a graphite composite including: anisotropic graphite 1 in which, given an X axis, a Y axis orthogonal to the X axis, and a Z axis perpendicular to the X-Y plane, crystal orientation planes 20 of graphite layers are disposed in parallel to the X-Z plane, the anisotropic graphite having a first principal face 30 parallel to the X-Y plane and a second principal face 31 opposing the first principal face 30; a first metal layer 3 provided on the first principal face 30 of the anisotropic graphite 1; a second metal layer 4 provided on the second principal face 31 of the anisotropic graphite 1; and an adhesive layer 11 and a reinforcing layer 10 provided on at least one face of the two faces in the anisotropic graphite 1 that are parallel to the Y-Z plane, wherein the first metal layer 3 and the second metal layer 4 each have a thickness of 2 μm to 50 μm, and the adhesive layer 11 contains resin.

As illustrated in FIG. 1, the graphite composite 101 according to an embodiment of the present disclosure includes the anisotropic graphite 1. The anisotropic graphite 1 has the first principal face 30 parallel to the X-Y plane and the second principal face 31 opposing the first principal face 30, in which crystal orientation planes 20 of graphite layers are disposed in parallel to the X-Z plane.

The anisotropic graphite 1 may have a block-like form, for example, a cube or a rectangular parallelepiped, in which many layers each having a graphite structure in which six-membered rings are linked together by covalent bonds to form graphite layers are stacked. Note that the anisotropic graphite 1 may be such that the stacked layers each having a graphite structure are in direct contact with each other, or may be such that the layers are stacked via an adhesive member for example, an adhesive or double-sided tape. The block-like anisotropic graphite has high thermal conductance in directions parallel to the crystal orientation planes 20 of the graphite layers, e.g., the X axis direction and the Z axis direction. The word “anisotropic” for the anisotropic graphite 1 means that the graphite layers are oriented and hence there is significant difference between the thermal conductance of the anisotropic graphite 1 in directions parallel to the crystal orientation planes 20 of the graphite layers, e.g., the X axis direction and the Z axis direction, and that in directions perpendicular to the crystal orientation planes 20 of the graphite layers, e.g., the Y axis direction. The anisotropic graphite 1 can be made by using a known technique such as a method described in WO 2019/188915 A1 mentioned above.

The thermal conductivity of the anisotropic graphite 1 in the X axis direction and that in the Z axis direction can be, for example, 1000 W/mK or more. The upper limit of the thermal conductivity of the anisotropic graphite 1 in the X axis direction and that in the Z axis direction is not limited to a particular value, and can be 2000 W/mK or less. On the other hand, the thermal conductivity of the anisotropic graphite 1 in the Y axis direction can be, for example, 0.3 W/mK or more and 20 W/mK or less.

The first principal face 30 is a face parallel to the X-Y plane, and the second principal face 31 is a face opposing the first principal face 30 parallel to the X-Y plane, in other words, a face parallel to the X-Y plane. Accordingly, the anisotropic graphite 1 is capable of efficient heat transport along the Z axis direction, e.g., from the first principal face 30 to the second principal face 31, and/or the X axis direction.

The thickness in the Z axis direction of the anisotropic graphite 1 is not limited, and preferably 0.3 mm to 5.0 mm, more preferably 0.5 mm to 3.0 mm, and most preferably 0.7 mm to 2.0 mm. This configuration enables achievement of a heat-transmitting element that is thin and capable of efficient heat transport.

The thickness of the anisotropic graphite 1 in the X axis direction and that in the Y axis direction are not limited, and can be appropriately set to fit the purpose of use. The thickness of the anisotropic graphite in the X axis direction and that in the Y axis direction can be, for example, 10 mm to 80 mm or 10 mm to 50 mm.

As illustrated in FIG. 1, the graphite composite 103 according to an embodiment of the present disclosure includes the first metal layer 3 provided on the first principal face 30 of the anisotropic graphite 1 and the second metal layer 4 provided on the second principal face 31 of the anisotropic graphite 1.

As described above, efficient heat transport occurs along the Z axis direction in the anisotropic graphite 1, and hence heat from the anisotropic graphite 1 can be efficiently transmitted to other structures through the first metal layer 3 and the second metal layer 4.

Since at least part of the surface of the anisotropic graphite 1 is covered by the first metal layer 3 and the second metal layer 4, the dispersion of graphite powder from the anisotropic graphite 1 can be prevented. Achievement of prevention of the dispersion of graphite powder from the anisotropic graphite 1 leads to successful prevention of short circuits caused by graphite powder in electronic circuits when the graphite composite according to an embodiment of the present disclosure is disposed in electronic equipment.

In addition, the anisotropic graphite 1 can be made further less susceptible to cracking by the first metal layer 3 and the second metal layer 4.

The first metal layer 3 and the second metal layer 4 may be provided so as to be in direct contact with the anisotropic graphite 1, or may be provided so as not to be in direct contact with the anisotropic graphite 1. It is preferable that the first metal layer 3 and the second metal layer 4 are provided so as to be in direct contact with the anisotropic graphite 1. This configuration allows direct acceptance and delivery of heat between the anisotropic graphite 1 and the first metal layer 3, and anisotropic graphite 1 and second metal layer 4, and hence a heat-transmitting element that is thin and capable of efficient heat transport can be achieved. In addition, with this configuration, at least part of the surface of the anisotropic graphite 1 can be more reliably covered by virtue of the first metal layer 3 and the second metal layer 4, and the anisotropic graphite 1 can be made less susceptible to cracking more reliably.

The first metal layer 3 and the second metal layer 4 are not limited to a particular configuration, and are each preferably a metal-deposited layer, a metal layer formed by sputtering treatment, a metal layer formed by thermal spraying, a plating layer, or a metal layer containing a metal brazing material, and more preferably a plating layer. Note that the plating layer may be an integrated product of a metal layer and an inorganic material layer. This configuration allows the first metal layer 3 and the second metal layer 4 to be thin, and hence a heat-transmitting element that is thin and capable of efficient heat transport can be achieved. In addition, this configuration allows the first metal layer 3 and the second metal layer 4 to be formed on the anisotropic graphite 1 without the intervention of any other structure.

The materials of the first metal layer 3 and the second metal layer 4 are not limited to particular materials, and each preferably contain at least one selected from the group consisting of copper, nickel, and gold. Among these materials, copper is more preferable. This configuration enables achievement of a heat-transmitting element with cost advantage and efficient heat transport in combination.

The thicknesses the Z axis direction of the first metal layer 3 and the second metal layer 4 may each be 2 μm to 50 μm, preferably 3 μm to 30 μm, and more preferably 5 μm to 10 μm. This configuration enables achievement of a heat-transmitting element capable of more efficient heat transport.

As illustrated in FIG. 1, in the graphite composite 103 according to an embodiment of the present disclosure, a third metal layer 5 and a fourth metal layer 6 are preferably respectively provided on one and the other outermost faces of the two faces in the anisotropic graphite 1 that are parallel to the X-Z plane.

Since at least part of the surface of the anisotropic graphite 1 is covered by the third metal layer 5 and the fourth metal layer 6, the dispersion of graphite powder from the anisotropic graphite 1 can be prevented.

In addition, the anisotropic graphite 1 can be made further less susceptible to cracking by the third metal layer 5 and the fourth metal layer 6.

The third metal layer 5 and the fourth metal layer 6 may be provided so as to be in direct contact with the anisotropic graphite 1, or may be provided so as not to be in direct contact with the anisotropic graphite 1. It is preferable that the third metal layer 5 and the fourth metal layer 6 are provided so as to be in direct contact with the anisotropic graphite 1. With this configuration, at least part of the surface of the anisotropic graphite 1 can be more reliably covered by virtue of the third metal layer 5 and the fourth metal layer 6, and the anisotropic graphite 1 can be made less susceptible to cracking.

The configuration of the third metal layer 5 and the fourth metal layer 6 can be the same as that of the first metal layer 3 and the second metal layer 4.

The thicknesses in the Y axis direction of the third metal layer 5 and the fourth metal layer 6 are not limited to particular values, and are each preferably 2 μm to 50 μm, more preferably 3 μm to 30 μm, and most preferably 5 μm to 10 μm. With this configuration, not only the dispersion of graphite powder from the anisotropic graphite 1 can be prevented, but also a thin heat-transmitting element can be achieved.

As illustrated in FIG. 1, the graphite composite 103 according to an embodiment of the present disclosure includes the reinforcing layer 10 provided on at least one face of the two faces of the anisotropic graphite 1 that are parallel to the Y-Z plane. In the graphite composite 103 according to an embodiment of the present disclosure, the reinforcing layer 10 is preferably provided on each face of the two faces in the anisotropic graphite 1 that are parallel to the Y-Z plane. Graphite composite 102 in FIG. 1 is a configuration in which the first metal layer 3, the second metal layer 4, the third metal layer 5, and the fourth metal layer 6 are not provided.

The anisotropic graphite has a character of susceptibility to cracking along the X-Z plane, represented by (crystal orientation planes 20. Accordingly, by providing the reinforcing layer 10 on at least one face of the two faces parallel to the Y-Z plane, the anisotropic graphite 1 can be made less susceptible to cracking.

A reinforcing layer may also be formed on the X-Z plane. That is, the graphite composite according to an embodiment of the present disclosure may include a reinforcing layer provided on at least one face of the two faces in the anisotropic graphite that are parallel to the X-Z plane.

The configuration on the outer side of the X-Z plane of the anisotropic graphite can be the same as the configuration on the outer side of the Y-Z plane of the anisotropic graphite. The configuration is, for example, a configuration including the reinforcing layer 10, a configuration including the reinforcing layer 10 and the adhesive layer 11, or a configuration including the reinforcing layer 10, the adhesive layer 11, and fifth metal layer 7.

The thicknesses in the X axis direction of the reinforcing layers 10 are not limited, and are each preferably 50 μm to 500 μm, more preferably 100 μm to 400 μm, and most preferably 150 μm to 300 μm. With this configuration, not only can the anisotropic graphite 1 be made less susceptible to cracking, but also a thin heat-transmitting element can be achieved.

The thicknesses of the reinforcing layers 10 in the Y axis direction and those in the Z axis direction are not limited, and can be appropriately set to fit the size of the anisotropic graphite 1.

The material of the reinforcing layer 10 is not limited to a particular material, and preferably contains at least one selected from the group consisting of resin, metal, and ceramic. Examples of the resin include acrylic resin, polypropylene, polyethylene, polyethylene terephthalate, polycarbonate, modified resin with addition of any additive, and elastomer. Examples of the metal include gold, silver, copper, nickel, aluminum, molybdenum, tungsten, alloy containing any of them, and metal brazing material. Examples of the ceramic include alumina, zirconia, silicon carbide, silicon nitride, boron nitride, and aluminum nitride. With this configuration, an advantage that the anisotropic graphite 1 can be made less susceptible to cracking can be obtained. For obtaining the advantage in a better manner, polycarbonate and polyethylene terephthalate are even more preferable among the resins, copper and aluminum are even more preferable among the metals, and alumina and silicon carbide are even more preferable among the ceramics.

As illustrated in FIG. 1, the graphite composite according to an embodiment of the present disclosure includes the adhesive layer 11 between the anisotropic graphite 1 and each of the reinforcing layers 10. With this configuration, the anisotropic graphite 1 and the reinforcing layers 10 can be adhered together via the adhesive layers 11.

The adhesive layer 11 contains resin. The resin is not limited, and may be, for example, at least one selected from the group consisting of thermosetting resin and thermoplastic resin. More specifically, the resin may be at least one selected from the group consisting of acrylic resin, silicone resin, epoxy resin, ester resin, phenolic resin, polyimide resin, and urethane resin. Also, the resin may be at least one selected from the group consisting of acrylic resin, silicone resin, and epoxy resin. The adhesive layer 11 may contain components other than the resin.

The thicknesses in the X axis direction of the adhesive layers 11 are not limited, and are each preferably 5 μm to 500 μm, more preferably 8 μm to 100 μm, and most preferably 8 μm to 50 μm. With this configuration, not only the anisotropic graphite 1 and the reinforcing layers 10 can be firmly adhered together, but also a thin heat-transmitting element can be achieved.

The thicknesses of the adhesive layers 11 in the Y axis direction and those in the Z axis direction are not limited, and can be appropriately set to fit the size of the anisotropic graphite 1.

The graphite composite 103 according to an embodiment of the present disclosure may include a fifth metal layer 7 on the outer side of each reinforcing layer 10, in other words, on the opposite side of each reinforcing layer 10 to the corresponding adhesive layer 11.

Since at least part of the surfaces of the reinforcing layers 10, i.e., at least part of the surface of the anisotropic graphite 1, is covered by the fifth metal layers 7, the dispersion of graphite powder from the anisotropic graphite 1 can be prevented in a better manner.

In addition, the anisotropic graphite 1 can be made further less susceptible to cracking by addition of the fifth metal layer 7.

The configuration of the fifth metal layers 7 is not limited to a particular configuration, and can be the same as that of the first metal layer 3 and the second metal layer 4.

The thicknesses in the X axis direction of the fifth metal layers 7 are not limited to particular values, and are each preferably 2 μm to 50 μm, more preferably 3 μm to 50 μm, and most preferably 5 μm to 10 μm. With this configuration, not only the dispersion of graphite powder from the anisotropic graphite 1 can be prevented, but also a thin heat-transmitting element can be achieved.

The thicknesses of the fifth metal layers 7 in the Y axis direction and those in the Z axis direction are not limited, and can be appropriately set to fit the size of the anisotropic graphite 1.

[2. Method for Producing Graphite Composite]

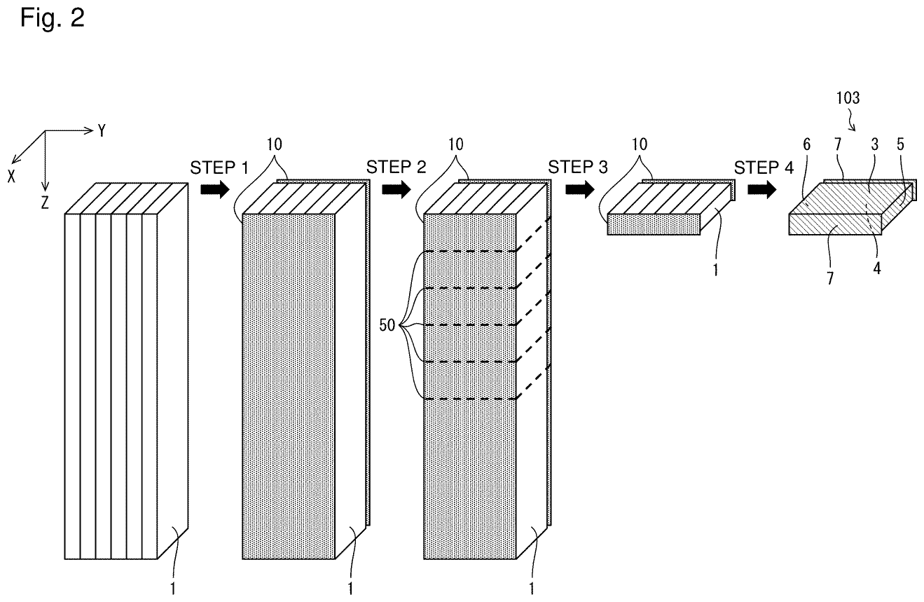

A method for producing a graphite composite 103 according to an embodiment of the present disclosure will be described with reference to FIG. 1 and FIG. 2. In the following, description is omitted for contents that have been described in the subsection [1. Graphite Composite].

The method for producing a graphite composite 103 according to an embodiment of the present disclosure is a method for producing a graphite composite 103 including anisotropic graphite 1 in which, given an X axis, a Y axis orthogonal to the X axis, and a Z axis perpendicular to the X-Y plane, crystal orientation planes 20 of graphite layers are disposed in parallel to the X-Z plane, the anisotropic graphite 1 having a first principal face 30 parallel to the X-Y plane and a second principal face 31 opposing the first principal face 30. The method includes a reinforcing step of forming a reinforcing layer 10 on at least one face of the two faces of the anisotropic graphite 1 that are parallel to the Y-Z plane, in which the anisotropic graphite 1 and the reinforcing layer 10 are adhered together via an adhesive layer 11; and a metal layer formation step of forming a first metal layer 3 and a second metal layer 4 respectively on the first principal face 30 and second principal face 31 of the anisotropic graphite 1 with the reinforcing layer 10 formed thereon. The first metal layer 3 and the second metal layer 4 each have a thickness of 2 μm to 50 μm, and the adhesive layer 11 contains resin.

The reinforcing step is a step of forming a reinforcing layer 10 on at least one face of the two faces of the anisotropic graphite 1 that are parallel to the Y-Z plane or on each face of the two faces of the anisotropic graphite 1 that are parallel to the Y-Z plane. See STEP 1 in FIG. 2.

The specific configuration of the reinforcing step is not limited; for example, the reinforcing layers 10 may each be adhered to the anisotropic graphite 1 via an adhesive layer 11. In adhering the anisotropic graphite 1 and the reinforcing layers 10 together via adhesive layers 11, a known method that fits the raw material of the adhesive layers 11 can be appropriately used.

The adhesive layer 11 contains resin. The resin is not limited, and may be, for example, at least one selected from the group consisting of thermosetting resin and thermoplastic resin. More specifically, the resin may be at least one selected from the group consisting of acrylic resin, silicone resin, epoxy resin, ester resin, phenolic resin, polyimide resin, and urethane resin. Also, the resin may be at least one selected from the group consisting of acrylic resin, silicone resin, and epoxy resin. The adhesive layer 11 may contain components other than the resin.

The method for producing the graphite composite 103 according to an embodiment of the present disclosure preferably includes a cutting step of cutting the reinforcing layers 10 and the anisotropic graphite 1 or the composite of the reinforcing layers 10 and the anisotropic graphite 1 after the reinforcing step.

In the cutting step, for example, the composite of the reinforcing layers 10 and the anisotropic graphite 1 can be cut along cutting planes 50 parallel to the X-Y plane. See STEP 2 to STEP 3 in FIG. 2. With this configuration, a plurality of precursors of the graphite composite 103 can be obtained from one large block. Furthermore, a plurality of graphite composites, each being the graphite composite 103, can be efficiently produced from the precursors.

The specific process in the cutting step is not limited, and examples thereof include cutting with a wire saw, cutting with a mold, and cutting with a laser. Among them, cutting with a wire saw is preferable because the advantage of productivity is obtained.

The metal layer formation step is a step of forming a first metal layer 3 and a second metal layer 4 respectively on the first principal face 30 and second principal face 31 of the anisotropic graphite 1 with the reinforcing layers 10 formed thereon. See STEP 4 in FIG. 2.

It is preferable to form the first metal layer 3 and the second metal layer 4 simultaneously in the metal layer formation step. With this configuration, graphite composites can be efficiently produced.

In the metal layer formation step, the first metal layer 3, the second metal layer 4, a third metal layer 5, and a fourth metal layer 6 may be simultaneously formed. In the metal layer formation step, fifth metal layers 7 may be simultaneously formed in addition to the first metal layer 3 to fourth metal layer 6. Furthermore, in the metal layer formation step, the fifth metal layers 7 may be formed simultaneously with the first metal layer 3 and the second metal layer 4, without forming the third metal layer 5 and/or the fourth metal layer 6. With this configuration, graphite composites with the dispersion of graphite powder from the anisotropic graphite 1 prevented in a better manner can be efficiently produced.

The manner of forming the first metal layer 3, the second metal layer 4, the third metal layer 5, the fourth metal layer 6, and the fifth metal layers 7 is not limited to a particular method, and a known method to fit the raw materials of these metal layers can be appropriately used. Examples of the method can include plating treatment, affixing of a metal film to which an adhesive has been attached, metal vapor deposition, and sputtering treatment. With that configuration, metal layers including the first metal layer 3 and the second metal layer 4 can be directly formed on the structure including the anisotropic graphite 1.

In the case that metal layers are formed on the anisotropic graphite 1 by plating treatment or the like and thereafter reinforcing layers 10 are provided to the anisotropic graphite 1, the anisotropic graphite 1 needs to be put in a plating bath while being gripped with a gripping tool in plating treatment thereof. Here, examples of the metal layers include the first metal layer 3, the second metal layer 4, the third metal layer 5, the fourth metal layer 6, and the fifth metal layers 7. At that time, parts lacking the formation of a metal layer are likely to be generated at contact points with the gripping tool in the surface of the anisotropic graphite 1. In this case, there arises a problem that dispersion of graphite powder from the anisotropic graphite 1 is likely to occur. In addition, there also arises a problem that the anisotropic graphite 1 is likely to crack due to vibrations or the like generated when forming a metal layer.

The mentioned problems can be solved by performing the metal layer formation step after the reinforcing step.

An embodiment of the present disclosure includes the disclosures described in the following [1] to [50].

[1] A graphite composite including:
anisotropic graphite in which, given an X axis, a Y axis orthogonal to the X axis, and a Z axis perpendicular to the X-Y plane, crystal orientation planes of graphite layers are disposed in parallel to the X-Z plane, the anisotropic graphite having a first principal face parallel to the X-Y plane and a second principal face opposing the first principal face;
a first metal layer provided on the first principal face of the anisotropic graphite;
a second metal layer provided on the second principal face of the anisotropic graphite; and
an adhesive layer and a reinforcing layer provided on at least one face of the two faces in the anisotropic graphite that are parallel to the Y-Z plane, wherein
the first metal layer and the second metal layer each have a thickness of 2 μm to 50 μm, and
the adhesive layer contains resin.

[2] The graphite composite according to [1], wherein a thickness of the anisotropic graphite in the X axis direction and a thickness thereof in the Y axis direction are each 10 mm to 80 mm.

[3] The graphite composite according to [1] or [2], wherein a thickness of the anisotropic graphite in the Z axis direction is 0.3 mm to 5.0 mm.

[4] The graphite composite according to any one of [1] to [3], wherein the reinforcing layer has a thickness of 50 μm to 500 μm.

[5] The graphite composite according to any one of [1] to [4], wherein the resin contained in the adhesive layer is at least one selected from the group consisting of thermosetting resin and thermoplastic resin.

[6] The graphite composite according to any one of [1] to [5], wherein the resin contained in the adhesive layer is at least one selected from the group consisting of acrylic resin, silicone resin, epoxy resin, ester resin, phenolic resin, polyimide resin, and urethane resin.

[7] The graphite composite according to any one of [1] to [6], wherein the resin contained in the adhesive layer is at least one selected from the group consisting of acrylic resin, silicone resin, and epoxy resin.

[8] The graphite composite according to any one of [1] to [7], wherein the first metal layer and the second metal layer are in direct contact with the anisotropic graphite.

[9] The graphite composite according to any one of [1] to [8], wherein the first metal layer and the second metal layer are each a metal-deposited layer, a metal layer formed by sputtering treatment, a metal layer formed by thermal spraying, a plating layer, or a metal layer containing a metal brazing material.

[10] The graphite composite according to any one of [1] to [9], wherein the first metal layer and the second metal layer each contain at least one selected from the group consisting of copper, nickel, and gold.

[11] The graphite composite according to any one of [1] to [10], wherein thicknesses of the first metal layer and the second metal layer in the Z axis direction are each 2 μm to 50 μm.

[12] The graphite composite according to any one of [1] to [11], wherein the reinforcing layer contains at least one selected from the group consisting of resin, metal, and ceramic.

[13] The graphite composite according to any one of [1] to [12], wherein the reinforcing layer is provided on each face of the two faces in the anisotropic graphite that are parallel to the Y-Z plane.

[14] The graphite composite according to any one of [1] to [13], wherein a thickness of the reinforcing layer in the X axis direction is 50 μm to 500 μm.

[15] The graphite composite according to any one of [1] to [14], wherein a third metal layer and a fourth metal layer are respectively provided on one and the other outermost faces of the two faces in the anisotropic graphite that are parallel to the X-Z plane.

[16] The graphite composite according to [15], wherein the third metal layer and the fourth metal layer are in direct contact with the anisotropic graphite.

[17] The graphite composite according to [15] or [16], wherein the third metal layer and the fourth metal layer are each a metal-deposited layer, a metal layer formed by sputtering treatment, a metal layer formed by thermal spraying, a plating layer, or a metal layer containing a metal brazing material.

[18] The graphite composite according to any one of [15] to [17], wherein the third metal layer and the fourth metal layer each contain at least one selected from the group consisting of copper, nickel, and gold.

[19] The graphite composite according to any one of [15] to [18], wherein thicknesses of the third metal layer and the fourth metal layer in the Y axis direction are each 2 μm to 50 μm.

[20] The graphite composite according to any one of [1] to [19], further including a fifth metal layer on an outer side of the reinforcing layer.

[21] The graphite composite according to [20], wherein the fifth metal layer is a metal-deposited layer, a metal layer formed by sputtering treatment, a metal layer formed by thermal spraying, a plating layer, or a metal layer containing a metal brazing material.

[22] The graphite composite according to [20] or [21], wherein the fifth metal layer contains at least one selected from the group consisting of copper, nickel, and gold.

[23] The graphite composite according to any one of [20] to [22], wherein a thickness of the fifth metal layer in the X axis direction is 2 μm to 50 μm.

[24] A method for producing a graphite composite including anisotropic graphite in which, given an X axis, a Y axis orthogonal to the X axis, and a Z axis perpendicular to the X-Y plane, crystal orientation planes of graphite layers are disposed in parallel to the X-Z plane, the anisotropic graphite having a first principal face parallel to the X-Y plane and a second principal face opposing the first principal face, the method including:
a reinforcing step of forming a reinforcing layer on at least one face of the two faces of the anisotropic graphite that are parallel to the Y-Z plane, in which the anisotropic graphite and the reinforcing layer are adhered together via an adhesive layer; and
a metal layer formation step of forming a first metal layer and a second metal layer respectively on the first principal face and second principal face of the anisotropic graphite with the reinforcing layer formed thereon, wherein
the first metal layer and the second metal layer each have a thickness of 2 μm to 50 μm, and
the adhesive layer contains resin.

[25] The method for producing a graphite composite according to [24], wherein a thickness of the anisotropic graphite in the X axis direction and a thickness thereof in the Y axis direction are each 10 mm to 80 mm.

[26] The method for producing a graphite composite according to [24] or [25], wherein a thickness of the anisotropic graphite in the Z axis direction is 0.3 mm to 5.0 mm.

[27] The method for producing a graphite composite according to any one of [24] to [26], wherein the reinforcing layer has a thickness of 50 μm to 500 μm.

[28] The method for producing a graphite composite according to any one of [24] to [27], including a cutting step of cutting the reinforcing layer and the anisotropic graphite after the reinforcing step.

[29] The method for producing a graphite composite according to any one of [28], wherein the cutting step is a step of cutting the reinforcing layer and the anisotropic graphite along cutting planes parallel to the X-Y plane.

[30] The method for producing a graphite composite according to any one of [28] or [29], wherein the cutting step is a step of cutting the reinforcing layer and the anisotropic graphite by a method selected from the group consisting of cutting with a wire saw, cutting with a mold, and cutting with a laser.

[31] The method for producing a graphite composite according to any one of [24] to [30], wherein the resin contained in the adhesive layer is at least one selected from the group consisting of thermosetting resin and thermoplastic resin.

[32] The method for producing a graphite composite according to any one of [24] to [31], wherein the resin contained in the adhesive layer is at least one selected from the group consisting of acrylic resin, silicone resin, epoxy resin, ester resin, phenolic resin, polyimide resin, and urethane resin.

[33] The method for producing a graphite composite according to any one of [24] to [32], wherein the resin contained in the adhesive layer is at least one selected from the group consisting of acrylic resin, silicone resin, and epoxy resin.

[34] The method for producing a graphite composite according to any one of [24] to [33], wherein the first metal layer and the second metal layer are simultaneously formed in the metal layer formation step.

[35] The method for producing a graphite composite according to any one of [24] to [34], wherein the first metal layer and the second metal layer are formed so as to be in direct contact with the anisotropic graphite in the metal layer formation step.

[36] The method for producing a graphite composite according to any one of [24] to [35], wherein the first metal layer and the second metal layer are each a metal-deposited layer, a metal layer formed by sputtering treatment, a metal layer formed by thermal spraying, a plating layer, or a metal layer containing a metal brazing material.

[37] The method for producing a graphite composite according to any one of [24] to [36], wherein the first metal layer and the second metal layer each contain at least one selected from the group consisting of copper, nickel, and gold.

[38] The method for producing a graphite composite according to any one of [24] to [37], wherein thicknesses of the first metal layer and the second metal layer in the Z axis direction are each 2 μm to 50 μm.

[39] The method for producing a graphite composite according to any one of [24] to [38], wherein the reinforcing layer contains at least one selected from the group consisting of resin, metal, and ceramic.

[40] The method for producing a graphite composite according to any one of [24] to [39], wherein the reinforcing layer is provided on each face of the two faces in the anisotropic graphite that are parallel to the Y-Z plane in the reinforcing step.

[41] The method for producing a graphite composite according to any one of [24] to [40], wherein a thickness of the reinforcing layer in the X axis direction is 50 μm to 500 μm.

[42] The method for producing a graphite composite according to any one of [24] to [41], wherein a third metal layer and a fourth metal layer are further respectively formed on one and the other outermost faces of the two faces in the anisotropic graphite that are parallel to the X-Z plane in the metal layer formation step.

[43] The method for producing a graphite composite according to [42], wherein the third metal layer and the fourth metal layer are formed so as to be in direct contact with the anisotropic graphite in the metal layer formation step.

[44] The method for producing a graphite composite according to [42] or [43], wherein the third metal layer and the fourth metal layer are each a metal-deposited layer, a metal layer formed by sputtering treatment, a metal layer formed by thermal spraying, a plating layer, or a metal layer containing a metal brazing material.

[45] The method for producing a graphite composite according to any one of [42] to [44], wherein the third metal layer and the fourth metal layer each contain at least one selected from the group consisting of copper, nickel, and gold.

[46] The method for producing a graphite composite according to any one of [42] to [45], wherein thicknesses of the third metal layer and the fourth metal layer in the Y axis direction are each 2 μm to 50 μm.

[47] The method for producing a graphite composite according to any one of [42] to [46], wherein a fifth metal layer is further formed on an outer side of the reinforcing layer in the metal layer formation step.

[48] The method for producing a graphite composite according to [47], wherein the fifth metal layer is a metal-deposited layer, a metal layer formed by sputtering treatment, a metal layer formed by thermal spraying, a plating layer, or a metal layer containing a metal brazing material.

[49] The method for producing a graphite composite according to [47] or [48], wherein the fifth metal layer contains at least one selected from the group consisting of copper, nickel, and gold.

[50] The method for producing a graphite composite according to any one of [47] to [49], wherein a thickness of the fifth metal layer in the X axis direction is 2 μm to 50 μm.

### EXAMPLES

The following describes an embodiment of the present disclosure in more detail with Examples and Comparative Examples, but the present disclosure is not limited by them.

### <Production of Anisotropic Graphite and Graphite Composite>

### Graphite Composite (A): Example 1

A total of 4500 polyimide films each having dimensions of 100 mm×100 mm× thickness 25 μm were stacked. Thereafter, while being pressurized at a pressure of 40 kg/cm², heat treatment was performed up to 2900 °C under an argon atmosphere, thereby making a graphite block (90 mm×90 mm, thickness: 45 mm). The obtained graphite block had a thermal conductivity of 1500 W/mK in a direction parallel to crystal orientation planes and a thermal conductivity of 5 W/mK in a direction perpendicular to the crystal orientation planes.

The obtained graphite block (90 mm×90 mm, thickness: 45 mm) was cut with a wire saw to give anisotropic graphite 1. The dimensions of the anisotropic graphite 1 were such that, as crystal orientation planes of the anisotropic graphite 1 were disposed in parallel to the X-Z plane, the length of each side parallel to the X axis was 39.6 mm, the length of each side parallel to the Y axis was 29.99 mm, and the length of each side parallel to the Z axis was 80 mm.

Next, oxygen-free copper of 29.99 mm×80 mm×thickness 150 μm as a reinforcing layer 10 was adhered on each face of the two faces of the anisotropic graphite 1 that were parallel to the Y-Z plane via acrylic double-sided tape of 29.99 mm×80 mm×50 μm as an adhesive layer 11.

By this method, a composite was obtained having a length of each side parallel to the X axis of 40 mm, a length of each side parallel to the Y axis of 29.99 mm, and a length of each side parallel to the Z axis of 80 mm.

Thereafter, the composite was cut in parallel to the X-Y plane with a wire saw to give a composite of arbitrary thickness. The obtained composite was subjected to plating treatment to precipitate copper having a thickness of 5 μm on the surface, giving graphite composite (A) coated by metal. The metal coating film corresponds to the first metal layer 3 and the second metal layer 4.

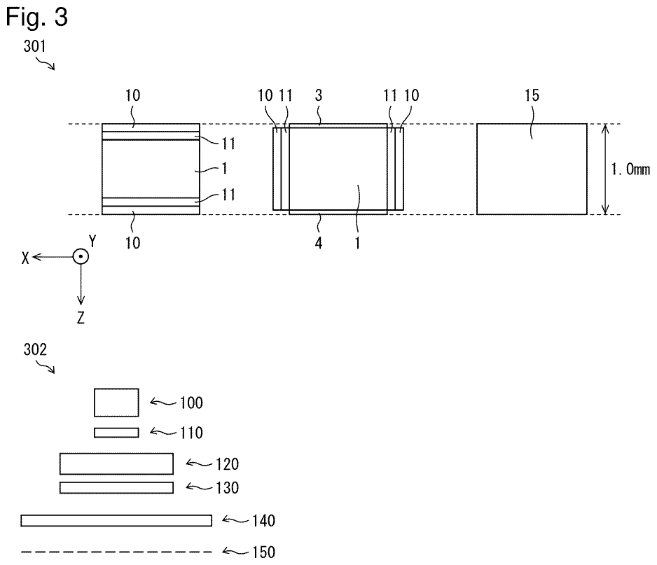

The schematic of the configuration of graphite composite (A) is shown in the center of the reference numeral 301 in FIG. 3, and the dimensions of graphite composite (A) are shown in the following:
size of anisotropic graphite 1 in X-Y plane: 39.6 mm×29.99 mm,
thickness of anisotropic graphite 1 in Z axis direction: 0.99 mm,
thicknesses of first metal layer 3 and second metal layer 4 in Z axis direction: 5 μm,
thicknesses of adhesive layers 11 in X axis direction: 50 μm,
thicknesses of adhesive layers 11 in Z axis direction: 0.99 mm,
thermal conductivity of adhesive layers 11: 0.2 W/mK,
thicknesses of reinforcing layers 10 in X axis direction: 150 μm, and
thicknesses of reinforcing layers 10 in Z axis direction: 0.99 mm.

### Example 2

Graphite composite (B) was obtained in the same manner as in Example 1, except that silicone double-sided tape was used instead of the acrylic double-sided tape.

### Example 3

Graphite composite (C) was obtained in the same manner as in Example 1, except that epoxy resin tape was used instead of the acrylic double-sided tape and the copper plates were adhered at 180 °C.

### Example 4

Graphite composite (D) was obtained in the same manner as in Example 1, except that acrylic plates were used instead of the oxygen-free copper plates as the reinforcing layers.

### Example 5

Graphite composite (E) was obtained in the same manner as in Example 2, except that acrylic plates were used instead of the oxygen-free copper plates as the reinforcing layers.

### Example 6

Graphite composite (F) was obtained in the same manner as in Example 3, except that acrylic plates were used instead of the oxygen-free copper plates as the reinforcing layers.

### Example 7

Graphite composite (G) was obtained in the same manner as in Example 1, except for the procedure set forth in the following (i).

(i) A graphite block (200 mm×200 mm, thickness 40 mm) was made by alternately stacking graphite sheets manufactured by Kaneka Corporation having a thickness of 36 μm and acrylic double-sided tape having a thickness of 5 μm.

Note that the obtained graphite block had a thermal conductivity of 1500 W/mK in a direction parallel to crystal orientation planes and a thermal conductivity of 3 W/mK in a direction perpendicular to the crystal orientation planes.

### Example 8

Graphite composite (H) was obtained in the same manner as in Example 7, except that silicone double-sided tape was used instead of the acrylic double-sided tape.

### Example 9

Graphite composite (I) was obtained in the same manner as in Example 7, except that epoxy resin tape was used instead of the acrylic double-sided tape and the copper plates were adhered at 180 °C.

### Example 10

Graphite composite (J) was obtained in the same manner as in Example 1, except for the procedure set forth in the following (ii).

(ii) A graphite block (200 mm×200 mm, thickness 40 mm) was made by alternately stacking graphite sheets manufactured by Kaneka Corporation having a thickness of 36 μm and a polyester adhesive having a thickness of 5 μm, and then hot-pressing the stacked body at 260 °C and 5 MPa for 5 minutes.

Note that the obtained graphite block had a thermal conductivity of 1500 W/mK in a direction parallel to crystal orientation planes and a thermal conductivity of 5 W/mK in a direction perpendicular to the crystal orientation planes.

### Example 11

Graphite composite (K) was obtained in the same manner as in Example 10, except that silicone double-sided tape was used instead of the acrylic double-sided tape.

### Example 12

Graphite composite (L) was obtained in the same manner as in Example 10, except that epoxy resin tape was used instead of the acrylic double-sided tape and the copper plates were adhered at 180 °C.

### Example 13

Graphite composite (M) was obtained in the same manner as in Example 1, except that the thickness of copper plating was set to 20 μm.

### Comparative Example 1

Graphite composite (N) was obtained in the same manner as in Example 1, except for the procedures set forth in the following (iii) and (iv).

(iii) Titanium-based active silver brazing having a thickness of 10 μm was used instead of the acrylic double-sided tape.

(iv) A composite of the anisotropic graphite 1, the adhesive layers 11, and the reinforcing layers 10 was adhered together by heating at 850 °C for 30 minutes under a vacuum environment of 1×10⁻³ Pa while applying a load of 100 kg/m² from the sides of the reinforcing layers 10 on both faces.

### Comparative Example 2

Graphite composite (O) was obtained in the same manner as in Example 1, except that no copper plates were adhered as reinforcing plates and copper plating was directly precipitated on the side surfaces.

### Comparative Example 3

Graphite composite (P) was obtained in the same manner as in Comparative Example 1, except for the procedure set forth in the following (v).

(v) Instead of the copper plating, oxygen-free copper plates were adhered also on the principal faces by using titanium-based active silver brazing having a thickness of 10 μm, by heating at 850 °C for 30 minutes under a vacuum environment of 1×10⁻³ Pa while applying a load of 100 kg/m².

### Comparative Example 4

Graphite composite (Q) was obtained in the same manner as in Example 1, except that, instead of the copper plating, oxygen-free copper plates were adhered at room temperature also on the principal faces by using acrylic double-sided tape having a thickness of 50 μm.

### <Evaluation of Strength>

Three-point bending test was carried out with a three-point bending apparatus (manufactured by IMADA CO., LTD.) at 50 mm/min to measure stress at rupture for the test sample. Samples with a stress of 20 N or more were evaluated as “Excellent”, those with a stress of 12 N or more were evaluated as “Good”, those with a stress of 8 N or more were evaluated as “Fair”, and those with a stress of less than 8 N were evaluated as “Bad”. Here, the evaluation results of strength mean that “Bad” is not favorable, “Fair” is more favorable than “Bad”, “Good” is more favorable than “Fair”, and “Excellent” is more favorable than “Good”, that is, the most favorable.

### <Evaluation of Heat Resistance>

The test sample was heated in an oven for 30 minutes, and a temperature at which a change in outer shape occurred was measured. Samples showing no change even at 500 °C were evaluated as “Excellent”, samples showing no change even at 300 °C were evaluated as “Good”, and samples showing no change even at 200 °C were evaluated as “Fair”. Here, the evaluation results of heat resistance mean that “Fair” is favorable, “Good” is more favorable than “Fair”, and “Excellent” is more favorable than “Good”, that is, the most favorable.

### <Evaluation of Thermal Diffusivity>

The thermal diffusivity in a thickness direction of the test sample was measured using a xenon flash analyzer manufactured by NETZSCH, LFA 467. Samples having a thermal diffusivity of 7 cm²/s or more were evaluated as “Excellent”, samples having a thermal diffusivity of 4 cm²/s or more were evaluated as “Good”, and samples having a thermal diffusivity of less than 4 cm²/s were evaluated as “Poor”. Here, the evaluation results of thermal diffusivity mean that “Poor” is not favorable, “Good” is more favorable than “Poor”, and “Excellent” is more favorable than “Good”, that is, the most favorable.

### <Evaluation of Warpage>

Using VR-5000 manufactured by KEYENCE CORPORATION, a difference between the maximum height and the minimum height of a principal face of the test sample ((maximum height)−(minimum height)) was measured, which was defined as warpage of the test sample. Samples having a warpage of less than 0.05 mm were evaluated as “Excellent”, samples having a warpage of less than 0.1 mm were evaluated as “Good”, samples having a warpage of less than 0.15 mm were evaluated as “Fair”, and samples having a warpage of 0.15 mm or more were evaluated as “Bad”. Here, the evaluation results of warpage mean that “Bad” is not favorable, “Fair” is more favorable than “Bad”, “Good” is more favorable than “Fair”, and “Excellent” is more favorable than “Good”, that is, the most favorable.

### [Test Results]

The test results are shown in Table 1 below. As is apparent from Table 1, the graphite composites of the present disclosure exhibited favorable evaluations in all of “strength”, “heat resistance”, “thermal diffusivity”, and “warpage”. That is, it was demonstrated that the graphite composites of the present disclosure have excellent thermal diffusion ability, reduced susceptibility of anisotropic graphite to cracking, excellent heat resistance, and a reduced degree of warpage.

TABLE 1

| | | | | Reinforcing | | Heat | Thermal | |
|---|---|---|---|---|---|---|---|---|
| | Graphite | Principal face | Adhesive layer | layer | Strength | resistance | diffusivity | Warpage |
| Example 1 | Graphitized PI laminate | Cu plating (5 | Acrylic double- | Cu plate | Good | Fair | Excellent | Good |
| | | μm) | sided tape | | | | | |
| Example 2 | Graphitized PI laminate | Cu plating (5 | Silicone double- | Cu plate | Good | Fair | Excellent | Good |
| | | μm) | sided tape | | | | | |
| Example 3 | Graphitized PI laminate | Cu plating (5 | Epoxy resin tape | Cu plate | Good | Good | Excellent | Excellent |
| | | μm) | | | | | | |
| Example 4 | Graphitized PI laminate | Cu plating (5 | Acrylic double- | Acrylic plate | Fair | Fair | Excellent | Good |
| | | μm) | sided tape | | | | | |
| Example 5 | Graphitized PI laminate | Cu plating (5 | Silicone double- | Acrylic plate | Fair | Fair | Excellent | Good |
| | | μm) | sided tape | | | | | |
| Example 6 | Graphitized PI laminate | Cu plating (5 | Epoxy resin tape | Acrylic plate | Fair | Good | Excellent | Excellent |
| | | μm) | | | | | | |
| Example 7 | GS/acrylic double- | Cu plating (5 | Acrylic double- | Cu plate | Good | Fair | Excellent | Good |
| | sided tape | μm) | sided tape | | | | | |
| Example 8 | GS/acrylic double- | Cu plating (5 | Silicone double- | Cu plate | Good | Fair | Excellent | Good |
| | sided tape | μm) | sided tape | | | | | |
| Example 9 | GS/acrylic double- | Cu plating (5 | Epoxy resin tape | Cu plate | Good | Fair | Excellent | Excellent |
| | sided tape | μm) | | | | | | |
| Example 10 | GS/polyester adhesive | Cu plating (5 | Acrylic double- | Cu plate | Good | Fair | Excellent | Good |
| | | μm) | sided tape | | | | | |
| Example 11 | GS/polyester adhesive | Cu plating (5 | Silicone double- | Cu plate | Good | Fair | Excellent | Good |
| | | μm) | sided tape | | | | | |
| Example 12 | GS/polyester adhesive | Cu plating (5 | Epoxy resin tape | Cu plate | Good | Fair | Excellent | Excellent |
| | | μm) | | | | | | |
| Example 13 | Graphitized PI laminate | Cu plating (20 | Acrylic double- | Cu plate | Good | Good | Good | Fair |
| | | μm) | sided tape | | | | | |
| Comparative | Graphitized PI laminate | Cu plating (5 | Brazing material | Cu plate | Good | Excellent | Excellent | Bad |
| Example 1 | | μm) | | | | | | |
| Comparative | Graphitized PI laminate | Cu plating (5 | — | Cu plating | Bad | Excellent | Excellent | Good |
| Example 2 | | μm) | | | | | | |
| Comparative | Graphitized PI laminate | Brazing | Brazing material | Cu plate | Excellent | Excellent | Poor | Bad |
| Example 3 | | material + Cu | | | | | | |
| | | plate | | | | | | |
| Comparative | Graphitized PI laminate | Acrylic double- | Acrylic double- | Cu plate | Excellent | Fair | Poor | Fair |
| Example 4 | | sided tape + | sided tape | | | | | |
| | | Cu plate | | | | | | |

### INDUSTRIAL APPLICABILITY

The present disclosure is applicable to heat-transmitting elements, more specifically, heat-transmitting elements for electronic equipment and devices.

What is claimed is:

1. A graphite composite comprising:
anisotropic graphite in which, given an X axis, a Y axis orthogonal to the X axis, and a Z axis perpendicular to an X-Y plane, crystal orientation planes of graphite layers are disposed in parallel to an X-Z plane, the anisotropic graphite having a first principal face parallel to an X-Y plane and a second principal face opposing the first principal face;
a first metal layer provided on the first principal face of the anisotropic graphite;
a second metal layer provided on the second principal face of the anisotropic graphite; and
an adhesive layer and a first reinforcing layer provided on a first face of the two faces in the anisotropic graphite that is parallel to the Y-Z plane, wherein
the first metal layer and the second metal layer each have a thickness of 2 μm to 50 μm, and
the adhesive layer contains resin.

2. The graphite composite according to claim 1, wherein a thickness of the anisotropic graphite in the X axis direction and a thickness thereof in the Y axis direction are each 10 mm to 80 mm, and
a thickness thereof in the Z axis direction is 0.3 mm to 5.0 mm.

3. The graphite composite according to claim 1, wherein the first reinforcing layer has a thickness of 50 μm to 500 μm.

4. The graphite composite according to claim 1, wherein the resin contained in the adhesive layer is at least one selected from the group consisting of acrylic resin, silicone resin, and epoxy resin.

5. The graphite composite according to claim 1, wherein the first metal layer and the second metal layer are in direct contact with the anisotropic graphite.

6. The graphite composite according to claim 1, wherein the first metal layer and the second metal layer each contain at least one selected from the group consisting of copper, nickel, and gold.

7. The graphite composite according to claim 1, wherein the first reinforcing layer contains at least one selected from the group consisting of resin, metal, and ceramic.

8. The graphite composite according to claim 1, further comprising a second reinforcing layer provided on a second face of the two faces in the anisotropic graphite that are parallel to the Y-Z plane.

9. The graphite composite according to claim 1, wherein a third metal layer and a fourth metal layer are respectively provided on one and an other outermost faces of the two faces in the anisotropic graphite that are parallel to the X-Z plane.

10. The graphite composite according to claim 9, wherein the third metal layer and the fourth metal layer are in direct contact with the anisotropic graphite.

11. The graphite composite according to claim 1, further comprising a fifth metal layer on an outer side of the reinforcing layer.

12. A method for producing a graphite composite comprising anisotropic graphite in which, given an X axis, a Y axis orthogonal to the X axis, and a Z axis perpendicular to the X-Y plane, crystal orientation planes of graphite layers are disposed in parallel to the X-Z plane, the anisotropic graphite having a first principal face parallel to the X-Y plane and a second principal face opposing the first principal face, the method comprising:
a reinforcing step of forming a reinforcing layer on at least one face of the two faces of the anisotropic graphite that are parallel to the Y-Z plane, in which the anisotropic graphite and the reinforcing layer are adhered together via an adhesive layer; and
a metal layer formation step of forming a first metal layer and a second metal layer respectively on the first principal face and second principal face of the anisotropic graphite with the reinforcing layer formed thereon, wherein
the first metal layer and the second metal layer each have a thickness of 2 μm to 50 μm, and
the adhesive layer contains resin.

13. The method for producing a graphite composite according to claim 12, further comprising a cutting step of cutting the reinforcing layer and the anisotropic graphite after the reinforcing step.

14. The method for producing a graphite composite according to claim 12, wherein the resin contained in the adhesive layer is at least one selected from the group consisting of acrylic resin, silicone resin, and epoxy resin.

15. The method for producing a graphite composite according to claim 12, wherein the first metal layer and the second metal layer are simultaneously formed in the metal layer formation step.

16. The method for producing a graphite composite according to claim 12, wherein a third metal layer and a fourth metal layer are further respectively formed on one and an other outermost faces of the two faces in the anisotropic graphite that are parallel to the X-Z plane in the metal layer formation step.

17. The method for producing a graphite composite according to claim 16, wherein a fifth metal layer is further formed on an outer side of the reinforcing layer in the metal layer formation step.
